(19) United States
(12) Patent Application Publication
(10) Pub. No.: US 2003/0083849 A1
(43) Pub. Date: May 1, 2003

(54) Statistical sampling process

(76) Inventors: Mason B. Cabot, San Francisco, CA (US); Frank Hady, Portland, OR (US)

Correspondence Address: FISH & RICHARDSON, PC, 4350 LA JOLLA VILLAGE DRIVE, SUITE 500, SAN DIEGO, CA, 92122, US

(21) Appl. No.: 10/002,060

(22) Filed: Oct. 31, 2001

(51) Int. Cl. G06F 9/44; H03F 1/26; G06F 15/00; H04B 15/00

(52) U.S. Cl. 702/189

(57) ABSTRACT

A method of sampling data includes gathering a first data sample during execution of a program, executing the program during a random inter-sample period and gathering a second data sample following the inter-sample period. The method may also include generating an inter-sample count and decrementing the inter-sample count to zero before gathering the second data sample.

### TECHNICAL FIELD

This invention relates to sampling instrumentation data.

### BACKGROUND

“Sampling” refers to obtaining data samples from an instrument that is performing a task, for example, a computer processor executing an application. “Instrumentation” refers to specific pieces of hardware that are used to record events, e.g., counters, registers and memory devices that store values reflecting the occurrence of events caused by the execution of the application.

Generally, to obtain a sample of data, a sampling program interrupts the application being executed by the computer processor and then executes the sampling program to obtain a data sample. The sampling program is executed several times to obtain a set of data samples. The set of data samples is used to determine the performance of the instrument while performing the application, for example, the level of memory utilization of a computer processor while executing a simulation application.

The frequency and duration of execution of the sampling program causes computer processor “perturbation”, i.e., a percentage of available execution cycles that are lost due to the execution of the sampling program. Also, the sampling program requires some amount of processing time for “overhead” operations, for example, storing the sampled data in memory, calculating performance analysis on the sampled data and determining when to interrupt the computer processor for execution of the sampling program, etc.

One way of reducing sampling overhead is to increase the sampling period, i.e., the time between the taking of samples. However, increasing the sampling period results in a set of samples that represent only the average performance of the system.

### DESCRIPTION OF DRAWINGS

FIG. 1 is a flowchart showing a sampling process;

FIG. 2 is a timing diagram depicting the performance of the process of FIG. 1;

FIG. 3 is a block diagram of computer hardware on which the sampling process may be implemented; and

FIG. 4 is a block diagram of an inter-sample count generator.

### DESCRIPTION

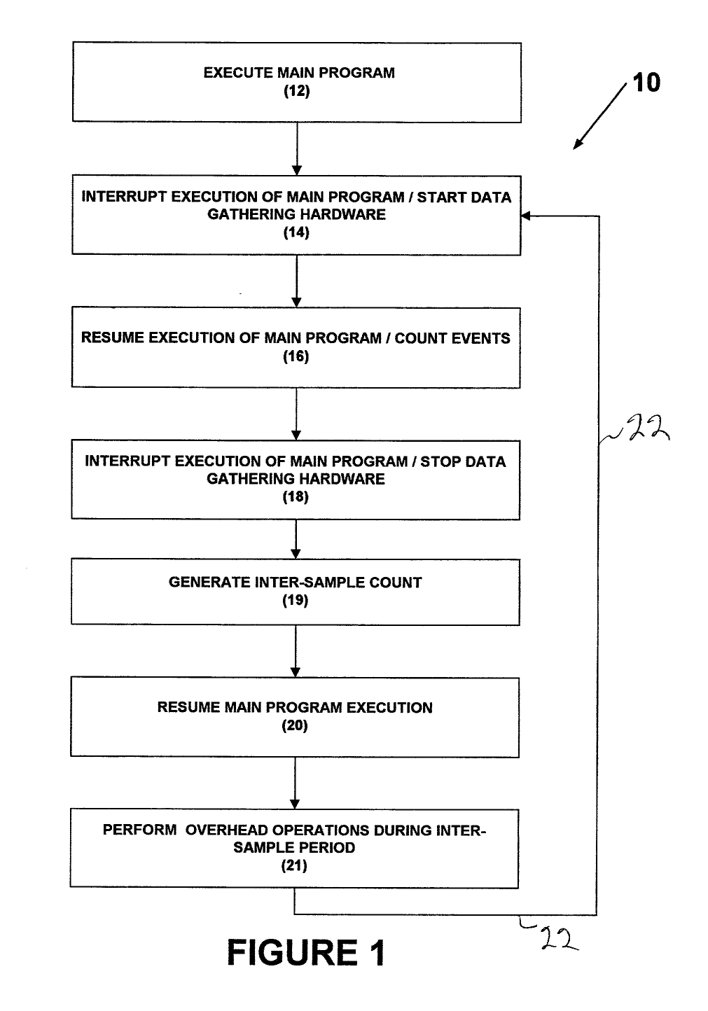

Referring to FIG. 1, a process 10 is shown for capturing a statistically distributed set of data samples obtained during execution of an application (a “main program”) by a computer processor. Process 10 obtains the data set during a series of sampling periods that are separated by random length “inter-sample” periods. By randomly varying the inter-sample periods process 10 obtains samples that are statistically distributed and enable a characterization of a relatively long segment of an executing application. Process 10 also reduces the perturbation to a computer processor being sampled by performing overhead operations and instructions between sampling periods, and completing those overhead operations before a subsequent sampling period begins.

Process 10 includes an iterative five-part process. Process 10 interrupts (14) the execution 12 of a main program to be sampled and starts (14) data gathering hardware. Process 10 resumes (16) execution of the main program, causing samples to be stored and/or counted by the data gathering hardware. Process 10 interrupts (18) execution of the main program and stops the data gathering hardware. Process 10 generates (19) a random inter-sample count. Process 10 resumes (20) execution of the main program and performs (21) overhead operations during the inter-sample time period. The inter-sample period is set to be sufficiently long to allow completion of the overhead operations before the next sampling period begins. When the inter-sample time period expires (22) process 10 is repeated to obtain more data samples.

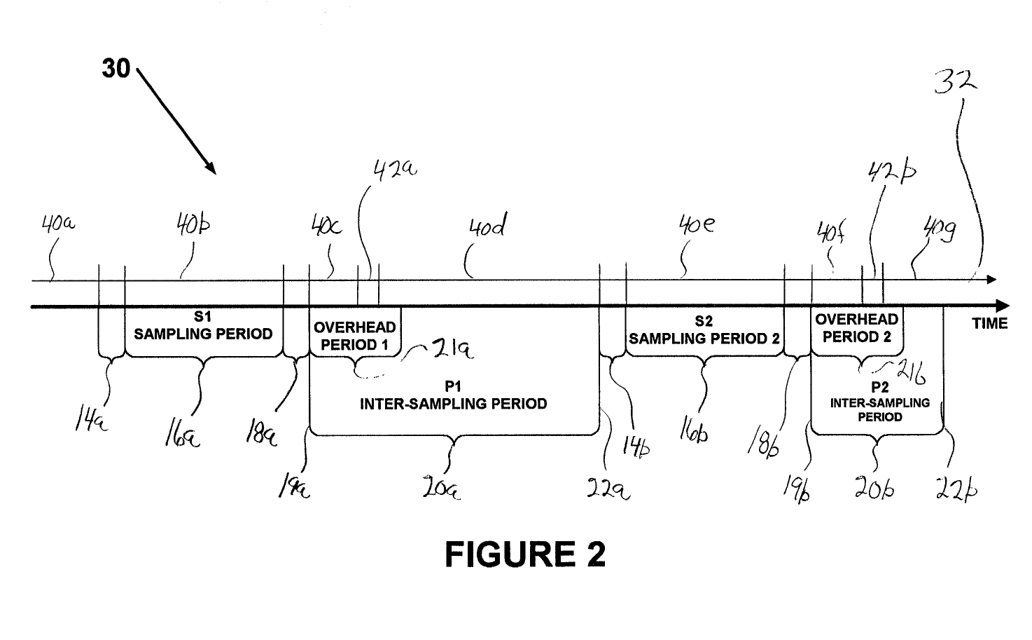

Referring to FIG. 2, timing diagram 30 depicts the execution of instructions by a computer processor that is executing a main program that is being sampled using sampling process 10. Timing diagram 30 includes an execution timeline 32 that shows the execution of main program instructions during periods 40a-40g that includes the gathering of samples during periods 40b and 40e based on sampling process 10. Referring to the previous discussion of process 10, timing diagram 30 depicts the iterative five parts of process 10: During period 14a, process 10 interrupts (14) the execution (12) of the main program and starts (14) data gathering hardware. Process 10 resumes (16) execution of the main program during period 16a, causing samples to be stored and/or counted by the data gathering hardware. During period 18a process 10 interrupts (18) execution of the main program and stops (18) the data gathering hardware. At time 19a, process 10 generates (19) a random inter-sample count. During period 20a, process 10 resumes (20) execution of the main program and performs (21) overhead operations during Overhead Period 21a, coinciding, in part, with the inter-sample time period 20a. When inter-sample time period 20a expires, at time 22a, process 10 is repeated to obtain more data samples during period 16b, and so forth. Performing 21 to overhead operations could include the action of generating 19 an inter-sample count, rather than generating 19 the inter-sample count before resuming 20 main program execution.

As described previously, and as shown in FIG. 2, during overhead periods 21a and 21b, any required overhead operations are performed, that is, operations that are not related to obtaining sample data. For example, overhead operations may include overhead instructions that may interrupt execution of the main program during periods 42a and 42b. Furthermore, overhead operations and instructions may include performance analysis calculations related to the obtained sample data (e.g., in the case of a ‘real-time’ performance analyzer program), decrementing of the inter-sample count, writing data samples obtained during the sampling period(s) to a memory, and/or re-setting data gathering hardware, etc. By performing the overhead operations outside of the sampling periods 16a and 16b, the perturbation to the computer processor within sampling periods is reduced.

The duration of each inter-sample period may be obtained by generating a random bit-pattern that is decremented during the execution of instructions by the computer processor. The random bit-pattern may be generated using hardware or software. However, it is noted that the inter-sample periods 20a and 20b are set to be sufficiently long to allow completion of overhead operations before the next sampling period begins. This may be obtained, for example, by adding a fixed period of execution time to the random inter-sample count. For example, the most significant bit (or bits) of the inter-sample bit-pattern may be set to one to increase the inter-sample count before the bit-pattern is decremented.

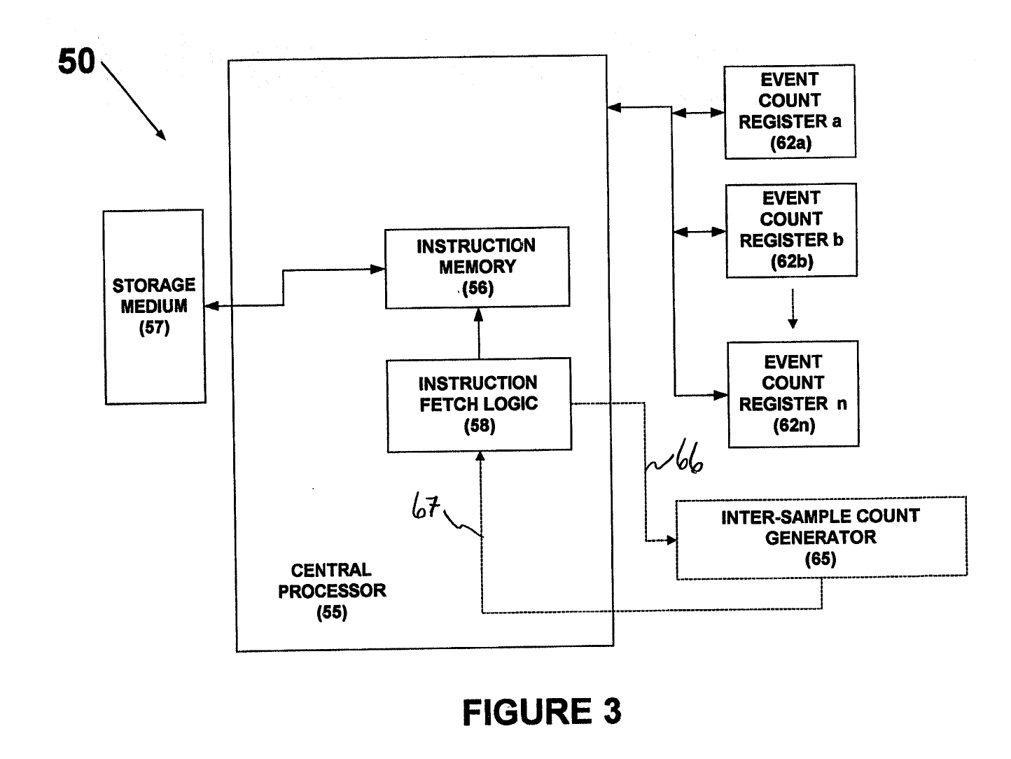

FIG. 3 shows a computer 50 on which process 10 may be implemented. Computer 50 includes a central processor unit (CPU) 55, an instruction memory 56, and a storage medium 57. Storage medium 57 stores data for one or more machine-executable instructions that are executed by CPU 55 out of instruction memory 56 to perform sampling process 10. Instruction memory 56 also stores instructions for both a main program to be sampled and a sampling program. CPU 55 also includes an instruction fetch logic block 58 for determining and selecting instructions from instruction memory 56 to be executed. Computer 50 also includes several event counter registers (ECR) 62a-62n that, when enabled, store values indicating the occurrence of events caused by the execution of main program instructions by CPU 55. It is noted that computer 50 may also be connected to other logic blocks or systems that could affect data sampling. For example, computer 50 may be connected to additional memory or storage systems, or connected to one or more input/output buses, or connected to interact with a graphics system.

Additional hardware may be included with computer 50. This additional hardware and their connections are shown in dotted lines on FIG. 3. For example, computer 50 may include an inter-sample count generator 65 connected to instruction fetch logic 58 by enable/disable line 66 and interrupt line 67. When enabled, inter-sample count generator 65 produces a random bit pattern that is used to determine when to generate an interrupt signal on line 67 to instruction fetch block 58. Instruction fetch logic block 58 uses interrupt signal 67 to determine when the sampling program will be executed by computer processor 55. Inter-sample count generator 65 may be implemented, for example, using a random number generator or a linear feedback shift register (LFSR).

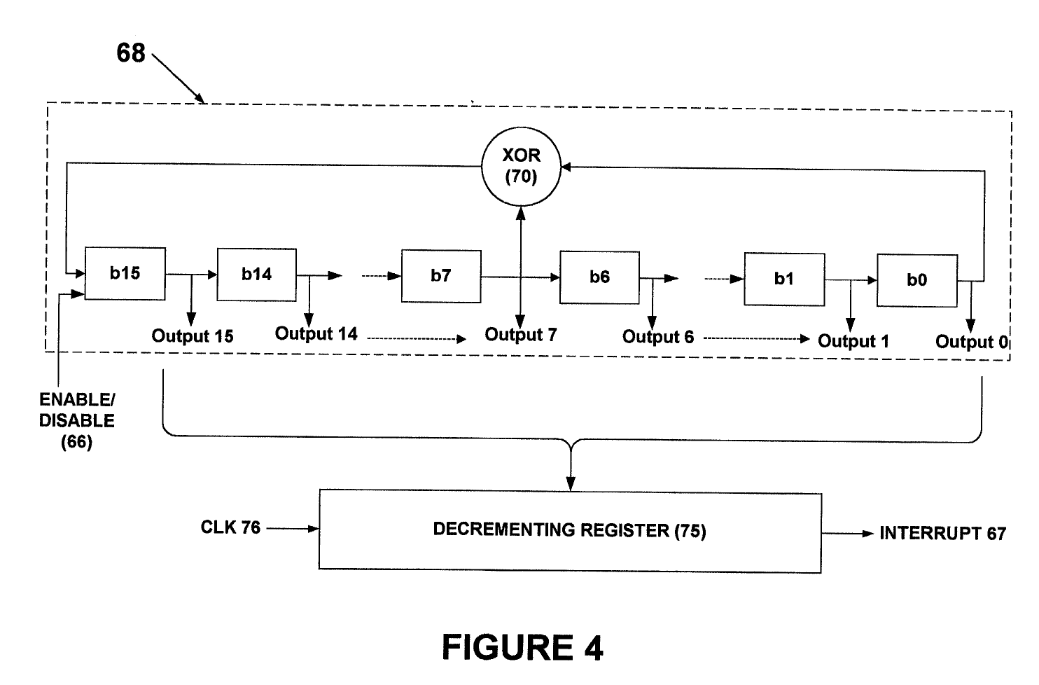

Referring to FIG. 4, inter-sample count generator 65 is shown implemented as an LFSR 68 connected to a decrementing register 75. LFSR 68 includes a series of bit latches b15-b0 and an XOR circuit 70 to generate a statistically random bit pattern at latch outputs Output15-Output0 that is input to decrementing register 75. LFSR 68 is configured to shift the contents of each bit latch b15-b0 from left to right, by one bit location when enabled by enable/disable signal 66. In this example of LFSR 68, the outputs of bit latches b7 and b0 are input to XOR 70, respectively, and the output of XOR 70 is stored in bit latch b15. This configuration of inputs and outputs to XOR 70 produces a random bit pattern at Output15-Output0. The resulting bit pattern output at Output15-Output0 represents the inter-sample count that is then input to decrementing register 75. Decrementing register 75 is also connected to receive a clock pulse CLK 65 that causes the inter-sample count to decrement to zero during execution of instructions by computer 50. When the inter-sample count reaches zero (0), an interrupt signal 67 is sent to fetch logic 58, as described previously. This configuration of LFSR 68 is a known way of producing a random number that is considered a “primitive trinomial”.

Inter-sample count generator 65 (see FIG. 3) may also be implemented in software. A software implementation of inter-sample count generator 65 may use registers (not shown) in computer processor 55 registers to store and generate bit patterns for producing a random inter-sample count.

Though specific embodiments have been described other ways to implement the features of those embodiments are possible. For example, multiple event counter registers 62a-62n were described as a part of computer 50, however, only a single register or counter or memory device may be used in order to obtain a data sample. The data gathering hardware was described as being “started” to gather a data sample. However, the data gathering hardware may be started by resetting the data gathering hardware. Also, event counter registers 62a-62n and inter-sample count generator 65 were described as separate from computer processor 55. However, either or both of event counter registers 62a-62n and inter-sample count generator 65 could be made part of the same physical package, for example, as part of the same integrated computer processor.

Process 10 is not limited to use with the hardware and software of FIGS. 3 and 4. It may find applicability in any computing or processing environment. Process 10 may be implemented in hardware, software, or a combination of the two. Process 10 may be implemented in computer programs executing on programmable computers or other machines that each include a computer processor, a storage medium readable by the computer processor (including volatile and non-volatile memory and/or storage components), at least one input device, and one or more output devices. Program code may be applied to data entered using an input device (e.g., a mouse or keyboard) to perform process 10 and to generate output information. Each such program may be implemented in a high level procedural or object-oriented programming language to communicate with a computer system. However, the programs can be implemented in assembly or machine language. The language may be a compiled or an interpreted language.

Each computer program may be implemented as one or more articles of manufacture (storage media), such as a CDROM, hard disk, or magnetic diskette, that is readable by a general or special purpose programmable computer for configuring and operating the computer when the storage medium or device is read by the computer to perform process 10. Process 10 may also be implemented as a machine-readable storage medium, configured with a computer program, where, upon execution, instructions in the computer program cause a machine to operate in accordance with process 10.

A number of embodiments of the invention have been described. Nevertheless, it will be understood that various modifications may be made without departing from the spirit and scope of the invention. Accordingly, other embodiments are within the scope of the following claims.

What is claimed is:

1. A method of sampling data, comprising:
gathering a first data sample during execution of a program;
executing the program during a random inter-sample period; and
gathering a second data sample following the inter-sample period.

2. The method of claim 1, wherein executing the program comprises:
generating an inter-sample count; and
decrementing the inter-sample count to zero before gathering the second data sample.

3. The method of claim 2, further comprising:
performing overhead operations during the inter-sample period.

4. The method of claim 3, wherein the inter-sample count is longer than an execution time required to perform the overhead operations.

5. The method of claim 3, wherein the overhead operations include at least one of decrementing the inter-sample count, storing a data sample, and performing a calculation based on a data sample.

6. The method of claim 1, wherein gathering the first data sample comprises:
resetting data gathering hardware,
executing the program during a sampling period; and
stopping the data gathering hardware at the end of the sampling period.

7. The method of claim 1, wherein gathering the first data sample comprises:
starting data gathering hardware,
executing the program during a sampling period; and
stopping the data gathering hardware at the end of the sampling period.

8. The method of claim 7, wherein the data gathering hardware comprises at least one event counter register.

9. The method of claim 2, wherein generating the inter-sample count comprises:
enabling a linear feedback shift register to produce a bit pattern.

10. The method of claim 9, wherein the linear feedback shift register is configured to produce a bit pattern that corresponds to a primitive trinomial.

11. An article comprising a machine-readable medium that stores machine-executable instructions for sampling data, the instructions causing a machine to:
gather a first data sample;
execute a program during a random inter-sample period; and
gather a second data sample following the inter-sample period.

12. The article of claim 11, wherein instructions causing a machine to execute the program comprises instructions causing a machine to:
generate an inter-sample count; and
decrement the inter-sample count to zero before gathering the second data sample.

13. The article of claim 12, comprising instructions causing the machine to:
perform overhead operations during the inter-sample period.

14. The article of claim 13, wherein instructions causing a machine to generate an inter-sample count comprise instructions causing a machine to:
generate an inter-sample count longer than an execution time required to perform the overhead operations.

15. The article of claim 13, wherein instructions causing a machine to perform overhead operations include instructions to cause a machine to perform at least one of decrement the inter-sample count, store the data sample, and perform a calculation based on a data sample.

16. The article of claim 11, wherein instructions causing a machine to gather a first data sample comprise instructions to cause a machine to:
start data gathering hardware;
gather the first data sample during execution the program; and
stop the data gathering hardware.

17. The article of claim 16, wherein the data gathering hardware comprises at least one event counter register.

18. The article of claim 12, wherein instructions causing a computer to generate an inter-sample count comprises instructions causing a machine to:
enable a linear feedback shift register to produce a bit pattern.

19. The article of claim 18, wherein the linear feedback shift register is configured to produce a bit pattern that corresponds to a primitive trinomial.

20. An apparatus for sampling data, comprising:
a memory that stores executable instructions; and
a computer processor that executes the instructions to:
gather a first data sample during execution of an application; and
gather a second data sample following an inter-sample period.

21. The apparatus of claim 20, wherein the computer processor further comprises:
a decrementing register, wherein the computer processor executes instructions to:
generate an inter-sample count,
store the inter-sample count in the decrementing register, and
decrement the inter-sample count to zero before gathering the second data sample.

22. The apparatus of claim 21, wherein the computer processor executes instructions to:
perform overhead operations during the inter-sample period.

23. The apparatus of claim 22, wherein the computer processor executes instructions to:
generate an inter-sample count that is longer than an execution time required to perform the overhead operations.

24. The apparatus of claim 22, wherein the computer processor executes instructions to:
perform overhead operations that include instructions for at least one of decrementing the inter-sample count, storing a data sample, and perform a calculation based on a data sample.

25. The apparatus of claim 20, wherein the computer processor comprises:
data gathering hardware, and wherein the computer processor executes instructions to:
start the data gathering hardware and stop the data gathering hardware.

26. The apparatus of claim 25, wherein the data gathering hardware comprises at least one event counter register.

27. The apparatus of claim 21, wherein the computer processor comprises:
a linear feedback shift register, and wherein the computer processor executes an instruction to enable the linear feedback shift register to produce a bit pattern that corresponds the inter-sample count.

28. The apparatus of claim 27, wherein the linear feedback shift register is configured to produce a bit pattern that corresponds to a primitive trinomial.
